(19) United States
(12) Patent Application Publication
(10) Pub. No.: US 2025/0029869 A1
(43) Pub. Date: Jan. 23, 2025

(54) ISOLATION STRUCTURE HAVING DIFFERENT LINERS ON UPPER AND LOWER PORTIONS

(71) Applicant: GlobalFoundries U.S. Inc., Malta, NY (US)

(72) Inventors: Jianwei Peng, Clifton Park, NY (US); Hong Yu, Clifton Park, NY (US)

(21) Appl. No.: 18/353,995

(22) Filed: Jul. 18, 2023

(51) Int. Cl. H01L 21/762; H01L 21/768

(52) U.S. Cl. CPC H01L 21/76224; H01L 21/76843

(57) ABSTRACT

An isolation structure for a substrate is disclosed. The isolation structure includes a lower portion having a first liner, and an upper portion having a second liner vertically over the first liner. A first dielectric material is surrounded by the second liner from above and by the first liner from below and laterally. The second liner may include a second dielectric material in at least part thereof. The second liner prevents exposure of end surfaces of a semiconductor layer of the substrate during subsequent processing, which prevents damage such as thinning, agglomeration and/or oxidation that can negatively affect performance of a transistor formed using the semiconductor layer. The second liner also reduces an overall step height of the isolation structure.

### BACKGROUND

The present disclosure relates to integrated circuit (IC) structures and, more particularly, to an isolation structure having upper and lower portions with different liners.

Isolation structures are used to electrically separate areas of a semiconductor layer in an IC structure. An isolation structure includes a single silicon nitride liner within a dielectric-filled trench. During formation, the dielectric material is recessed within the trench, which can damage the single liner and can lead to thinning, agglomeration, and oxidation of the exposed end surfaces of the semiconductor layer during subsequent processing. The agglomeration and oxidization of the end surfaces of the semiconductor layer can negatively affect performance of a transistor, such as increased current leakage.

### SUMMARY

All aspects, examples and features mentioned below can be combined in any technically possible way.

An aspect of the disclosure provides an isolation structure for a substrate, the isolation structure comprising: a lower portion having a first liner; an upper portion having a second liner vertically over the first liner; and a first dielectric material surrounded by the second liner from above and by the first liner from below and laterally.

An aspect of the disclosure provides an isolation structure for a substrate, the isolation structure comprising: a lower portion having a first U-shaped liner and a first dielectric material within the first U-shaped liner; and an upper portion over the lower portion, the upper portion having a second U-shaped liner and a second dielectric material within at least part of the second U-shaped liner, wherein a lower section of the second U-shaped liner contacts an upper surface of the first dielectric material.

An aspect of the disclosure provides a method, comprising: forming a first U-shaped liner within a trench extending through a semiconductor layer of a substrate; filling at least a portion of the trench with a first dielectric material; forming a second U-shaped liner in the trench over the first dielectric material in the trench and below an upper surface of the semiconductor layer; and filling at least part of the second U-shaped liner with a second dielectric material.

Two or more aspects described in this disclosure, including those described in this summary section, may be combined to form implementations not specifically described herein. The details of one or more implementations are set forth in the accompanying drawings and the description below. Other features, objects and advantages will be apparent from the description and drawings, and from the claims.

### BRIEF DESCRIPTION OF THE DRAWINGS

The embodiments of this disclosure will be described in detail, with reference to the following figures, wherein like designations denote like elements, and wherein:

FIG. 1 shows a cross-sectional view of a preliminary structure for a method forming an isolation structure including a first liner, according to embodiments of the disclosure;

FIG. 2 shows a cross-sectional view of recessing an initial isolation structure, according to embodiments of the disclosure;

FIG. 3 shows a cross-sectional view of forming a second liner, according to embodiments of the disclosure;

FIG. 4 shows a cross-sectional view of forming a dielectric material in the second liner, according to embodiments of the disclosure;

FIG. 5 shows a cross-sectional view of planarizing the dielectric material in the second liner, according to embodiments of the disclosure;

FIG. 6 shows a cross-sectional view of removing a mask, according to embodiments of the disclosure;

FIG. 7 shows a cross-sectional view of an isolation structure, according to embodiments of the disclosure; and

FIG. 8 shows a cross-sectional view of an isolation structure, according to other embodiments of the disclosure.

It is noted that the drawings of the disclosure are not necessarily to scale. The drawings are intended to depict only typical aspects of the disclosure, and therefore should not be considered as limiting the scope of the disclosure. In the drawings, like numbering represents like elements between the drawings.

### DETAILED DESCRIPTION

In the following description, reference is made to the accompanying drawings that form a part thereof, and in which is shown by way of illustration specific illustrative embodiments in which the present teachings may be practiced. These embodiments are described in sufficient detail to enable those skilled in the art to practice the present teachings, and it is to be understood that other embodiments may be used and that changes may be made without departing from the scope of the present teachings. The following description is, therefore, merely illustrative.

It will be understood that when an element such as a layer, region, or substrate is referred to as being “on” or “over” another element, it may be directly on the other element or intervening elements may also be present. In contrast, when an element is referred to as being “directly on” or “directly over” another element, there may be no intervening elements present. It will also be understood that when an element is referred to as being “connected” or “coupled” to another element, it may be directly connected or coupled to the other element or intervening elements may be present. In contrast, when an element is referred to as being “directly connected” or “directly coupled” to another element, there are no intervening elements present.

Reference in the specification to “one embodiment” or “an embodiment” of the present disclosure, as well as other variations thereof, means that a particular feature, structure, characteristic, and so forth described in connection with the embodiment is included in at least one embodiment of the present disclosure. Thus, the phrases “in one embodiment” or “in an embodiment,” as well as any other variations appearing in various places throughout the specification are not necessarily all referring to the same embodiment. It is to be appreciated that the use of any of the following “/,” “and/or,” and “at least one of,” for example, in the cases of “A/B,” “A and/or B” and “at least one of A and B,” is intended to encompass the selection of the first listed option (A) only, or the selection of the second listed option (B) only, or the selection of both options (A and B). As a further example, in the cases of “A, B, and/or C” and “at least one of A, B, and C,” such phrasing is intended to encompass the first listed option (A) only, or the selection of the second listed option (B) only, or the selection of the third listed option (C) only, or the selection of the first and the second listed options (A and B), or the selection of the first and third listed options (A and C) only, or the selection of the second and third listed options (B and C) only, or the selection of all three options (A and B and C). This may be extended, as readily apparent by one of ordinary skill in the art, for as many items listed.

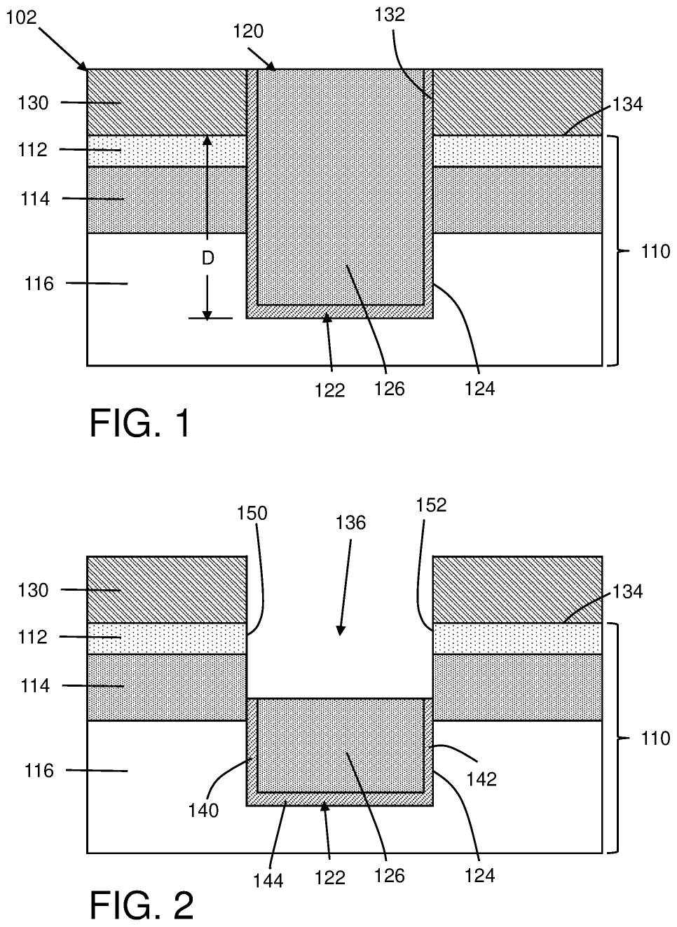

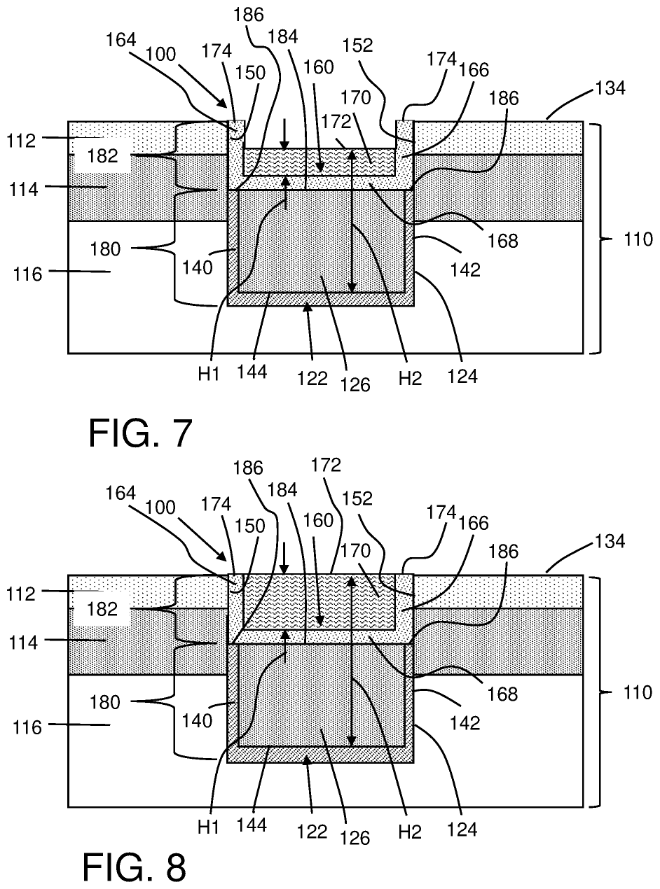

FIGS. 1-7 show cross-sectional views of a method of forming an isolation structure 100 (FIG. 7) according to embodiments of the disclosure. As understood by those with skill in the art, an isolation structure, also referred to as a trench isolation, typically includes a trench filled with a dielectric material, to isolate one region of a substrate from an adjacent region of the substrate. One or more transistors of a given polarity or other devices may be disposed within an area isolated by the isolation structure. As noted, an isolation structure for a substrate may include a single silicon nitride liner within a dielectric-filled trench. During formation, the dielectric material is recessed within the trench, which can damage the single liner and can lead to thinning, agglomeration, and oxidation of the exposed end surfaces of the semiconductor layer during subsequent processing. The agglomeration and oxidization of the end surfaces of the semiconductor layer can negatively affect performance of the transistor, such as increased current leakage.

Embodiments of the disclosure include an isolation structure for a substrate and a related method of forming the isolation structure. The isolation structure includes a lower portion having a first liner, and an upper portion having a second liner vertically over the first liner. A first dielectric material is surrounded by the second liner from above and by the first liner from below and laterally. The second liner may include a second dielectric material in at least part thereof. The second liner prevents exposure of end surfaces of a semiconductor layer of the substrate during subsequent processing, which prevents damage such as thinning, agglomeration, and/or oxidation that can negatively affect performance of a transistor formed using the semiconductor layer. The second liner also reduces an overall step height of the isolation structure.

FIG. 1 shows a cross-sectional view of a preliminary structure 102 for a method of forming isolation structure 100 (FIG. 6), according to embodiments of the disclosure. Preliminary structure 102 includes a substrate 110. For purposes of description, substrate 110 is illustrated and described as a semiconductor-on-insulator (SOI) substrate. An SOI substrate includes a layered semiconductor-insulator-semiconductor substrate in place of a more conventional silicon substrate (bulk substrate). Substrate 110 includes a semiconductor layer 112, sometimes referred to as a semiconductor-on-insulator (SOI) layer, over a buried insulator layer 114 over a base semiconductor layer 116. Semiconductor layer 112 and base semiconductor layer 116 may include any semiconductor material described herein. For example, semiconductor layer 112 may include silicon germanium (SiGe) and base semiconductor layer 116 may include silicon (Si), germanium (Ge), SiGe, silicon carbide, among other semiconductor materials. Buried insulator layer 114 may include any appropriate dielectric such as but not limited to silicon dioxide, i.e., forming a buried oxide (BOX) layer. A portion of or the entire semiconductor substrate, including semiconductor layer 112, may be stressed. For example, semiconductor layer 112 may include a compressive SiGe for improving performance of a p-type transistor to be formed therein. The precise thickness of buried insulator layer 114 and semiconductor layer 112 may vary widely with the intended application. In certain embodiments, substrate 110 may be a fully depleted SOI (FDSOI) substrate. FDSOI substrates use a very thin buried insulator layer 114 (e.g., 5-100 nanometers (nm)) and an ultra-thin semiconductor layer 112 (e.g., 5-100 nm) over buried insulator layer 114 that provides the transistor channel. The ultra-thin semiconductor layer 112 does not need to be doped to create the channel, thus making the transistor “fully depleted.” The ultra-thin semiconductor layer 112 in an FDSOI substrate is especially vulnerable to damage caused by recessing of an isolation structure extending through it. While embodiments of the disclosure will be described relative to an SOI or FDSOI substrate 110, the teachings of the disclosure are applicable to an isolation structure for any semiconductor layer (e.g., SOI or bulk) requiring protection from damage caused by isolation structure formation.

Preliminary structure 102 includes an initial isolation structure 120. Initial isolation structure 120 may be formed by forming a first liner 122 within a trench 124 extending through (at least) semiconductor layer 112 of substrate 110 and filling a remaining portion of trench 124 with a first dielectric material 126. More particularly, a mask 130 may be formed over substrate 110 and patterned to define opening 132 that can be used to etch trench 124 into substrate 110. Mask 130 may include any now known or later developed masking material such as but not limited to photoresist (resist) and nitride. Nitride is usually considered to be a “hard mask. Mask 130 may include a developable organic planarization layer (OPL) on the layer to be etched, a developable anti-reflective coating (ARC) layer on the developable OPL, and a photoresist mask layer on the developable ARC layer (different layers not shown for clarity). After processing, as will be described, the underlying layer, mask 130 may be removed. Mask 130 may be removed using any known removal process appropriate for the mask material, e.g., a wet etch for hard nitride mask or an ashing process (oxygen dry strip process) for a soft resist-based mask, or planarization process such as chemical mechanical polishing. Possible oxide and/or nitride capping layers between semiconductor layer 112 and mask 130 have been omitted for clarity. The etching process to form trench 124 may include any etching chemistry appropriate for substrate 110, e.g., a reactive ion etch.

First liner 122 may be deposited in trench 124 using any appropriate deposition technique for the liner material used. In certain embodiments, first liner 122 may include at least one of silicon nitride and silicon oxynitride, and may be deposited using chemical vapor deposition (CVD). First liner 122 may be U-shaped and thus may also be referenced herein as “first U-shaped liner 122.”

FIG. 1 also shows filling a remaining portion of trench 124, i.e., that part not filled by first liner 122, with a first dielectric material 126 to form initial isolation structure 120. First dielectric material 126 may be deposited using any appropriate deposition technique for the first dielectric material 126 used. In certain embodiments, first dielectric material 126 may include an oxide and be deposited using CVD. Other materials (and deposition techniques) may also be used, such as but not limited to: fluorinated SiO₂ (FSG), hydrogenated silicon oxycarbide (SiCOH), porous SiCOH, boro-phospho-silicate glass (BPSG), silicon carbon-nitride (SiCN) and silicon carbide materials. Any excess material may be removed using an appropriate planarization technique, such as but not limited to chemical mechanical polishing (CMP).

Trench 124 may extend into substrate 110 to any desired depth D to ensure electrical isolation for devices to be subsequently built on or into substrate 110. In this regard, trench 124 may have a depth D (relative to an upper surface 134 of semiconductor layer 112 of substrate 110) that would result in an isolation structure that is considered to be a shallow trench isolation structure with a depth D of, for example, 10-100 nm, or a deep trench isolation structure with a depth D of, for example, 50-1000 nm.

FIG. 2 shows a cross-sectional view of recessing initial isolation structure 120, according to embodiments of the disclosure. The recessing may include any etching chemistry appropriate for first dielectric material 126, e.g., a reactive ion etch, and/or stripping process to remove first liner 122. As shown in FIG. 2, the recessing removes first dielectric material 126 from an upper section of trench 124, creating a recessed area 136. In addition, the recessing removes at least part of first liner 122, e.g., from sidewalls of mask 130, end surfaces 150, 152 of semiconductor layer 112 and sidewalls of buried insulator layer 114. As illustrated, the recessing causes first liner 122 to be shortened in height but retain the afore-mentioned U-shape. At this stage, first liner 122 includes a first leg 140, a second leg 142 and a bight portion 144 coupling legs 140, 142. A depth of recessed area 136 may be user defined, but typically extends into at least buried insulator layer 114 to expose end surfaces 150, 152 of semiconductor layer 112. FIGS. 1-2 thus show filling at least a portion of trench 124 with first dielectric material 126. Other methodologies may also be possible to arrive at the same structure as shown in FIG. 2.

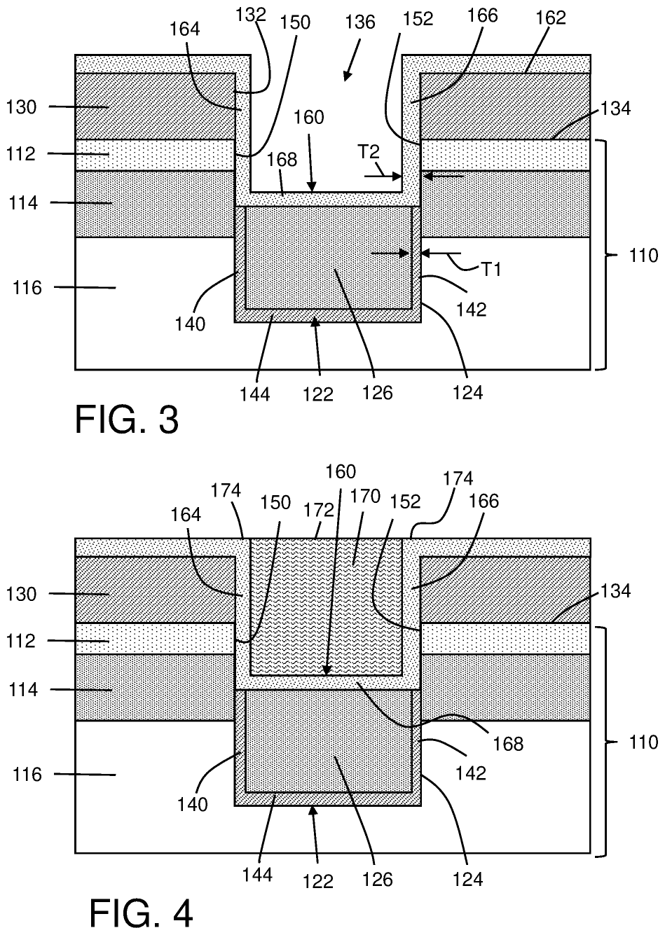

FIG. 3 shows a cross-sectional view of forming a second liner 160, according to embodiments of the disclosure. More particularly, FIG. 3 shows forming second liner 160 in trench 124 over first dielectric material 126 and first liner 122 in trench 124. Second liner 160, as will be further described, may be U-shaped and thus may also be referenced herein as “second U-shaped liner 160.” As illustrated, because recessed area 136 extends below upper surface 134 of semiconductor layer 112, second liner 160 extends below upper surface 134 of semiconductor layer 112, i.e., in trench 124. Second liner 160 abuts end surfaces 150, 152 of semiconductor layer 112, i.e., it covers end surfaces 150, 152. In this arrangement, as will be further described, second liner 160 protects semiconductor layer 112 from damage from subsequent processing such as thinning, agglomeration or oxidation. Second liner 160 includes a different material than first liner 122. In certain embodiments, second liner 160 includes at least one of silicon oxy-carbonitride (SiOCN), silicon carbo-nitride (SiCN) and silicon boro-carbon nitride (SiBCN). The materials for second liner 160 have a slower etch rate than first liner 122.

Second liner 160 is also thicker than first liner 122. More particularly, recessed area 136 is not as deep as initial trench 124, which allows a second liner 160 to be formed thicker than first liner 122. As shown in FIG. 3, first liner 122 may have a thickness T1 that is thinner than a thickness T2 of second liner 160. In one non-limiting example, second liner 160 may have a thickness T2 in a range of 6-14 nm, and first liner 122 may have a thickness T1 in a range of 4-12 nm. Second liner 160 also extends over an upper surface 162 of mask 130. As noted, second liner 160 has a U-shape within recessed area 136. More particularly, second liner 160 includes a first leg 164, a second leg 166 and a bight portion 168 coupling legs 164, 166.

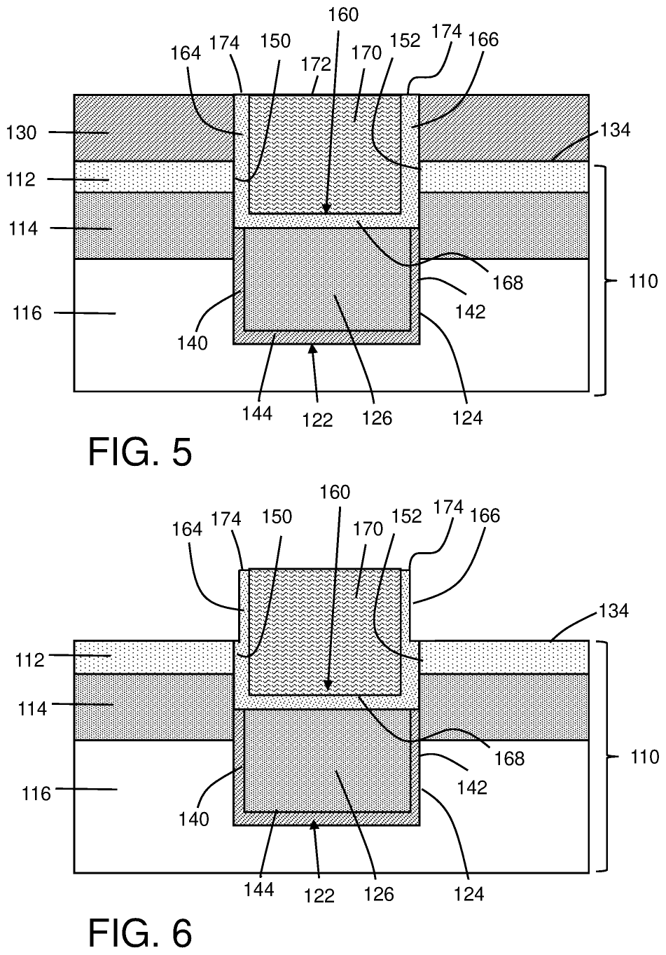

FIGS. 4-5 show cross-sectional views of forming a second dielectric material 170 in second liner 160, according to embodiments of the disclosure. Forming second dielectric material 170 includes at least partially filling second liner 160 with second dielectric material 170. In FIG. 4, all of recessed area 136 and second liner 160 is shown filled, i.e., an upper surface 172 of second dielectric material 170 is coplanar with upper end surfaces 174 of legs 164, 166 of second liner 160. However, as will be described, upper surface 172 of second dielectric material 170 may eventually not be coplanar with upper end surfaces 174 of legs 164, 166 of second liner 160. Further, upper surface 172 of second dielectric material 170 may eventually be below upper surface 134 of semiconductor layer 112. Second dielectric material 170 may be deposited using any appropriate deposition technique for the second dielectric material 170 used. In certain embodiments, second dielectric material 170 may include an oxide and be deposited using high density plasma chemical vapor deposition (HPD-CVD), forming an HDP-CVD oxide. HDP-CVD oxide has higher density than first dielectric material 126, regardless of the latter material's form. Other dielectric materials as listed herein (and deposition techniques) may also be used. In any event, first dielectric material 126 is different than second dielectric material 170. As shown in FIG. 5, any excess material may be removed using any appropriate planarization technique, such as but not limited to chemical mechanical polishing (CMP). The planarization may also remove second liner 160 from over mask 130.

FIG. 6 shows a cross-sectional view of removing mask 130, according to embodiments of the disclosure. Mask 130 may be removed using any now known or later developed technique appropriate for the mask material, such as but not limited to a wet etch for a hard nitride mask. As shown, second liner 160 does not etch as quickly as mask 130 and so remains, protecting second dielectric material 170 therein.

FIG. 7 shows a cross-sectional view of isolation structure 100, according to embodiments of the disclosure. Isolation structure 100 is shown after additional processing that causes second dielectric material 170 and second liner 160 to be initially coplanar with upper surface 134 of semiconductor layer 112, and eventually causes upper surface 172 of second dielectric material 170 to be below upper surface 134 of semiconductor layer 112. The additional processing may include but is not limited to: wet etches such as dilute hydrofluoric (DHF) acid wet cleans, and thermal processing such as those used for driving in dopants to semiconductor layer 112. The processing reduces a height H1 of second dielectric material 170 and the overall step height H2 of isolation structure 100. The processing also consumes some of second liner 160, but the thickness and materials of second liner 160 do not allow the processing to affect semiconductor layer 112 in a negative fashion. That is, second liner 160 continues to protect semiconductor layer 112 from damage such as thinning, agglomeration and oxidation. FIG. 8 shows other embodiments in which the processing does not affect second dielectric material 170 as much as in FIG. 7. In FIG. 8, second dielectric material 170 fills more of the U-shape of second liner 160 than shown in FIG. 7, and may include upper surface 172 coplanar, or closer to coplanar, with upper surface 134 of semiconductor layer 112.

Additional conventional processing, not shown in FIGS. 7-8, can be performed with isolation structure 100 completed. The additional processing may include any now known or later developed front-end-of-line (FEOL) processing to build active devices like transistors, and/or middle-of-line (MOL) and back-end-of-line (BEOL) processing to, among other things, provide electrical interconnections between active devices. The additional processing may also fill a space above isolation structure 100 with, among other things, additional dielectric material, such as an interlayer dielectric material.

Referring to FIGS. 7 and 8, isolation structure 100 for substrate 110 includes a lower portion 180 having first liner 122, and an upper portion 182 having second liner 160 vertically over first liner 122. First dielectric material 126 is surrounded by: second liner 160 from above (i.e., by a lower part of bight portion 168 from above) and by first liner 122 from below (i.e., by bight portion 144 of first liner 122) and laterally (i.e., by legs 140, 142 of first liner 122). Second liner 160 abuts end surfaces 150, 152 of semiconductor layer 112 of substrate 110, protecting it from damage. Second liner 160 is U-shaped, and second dielectric material 170 is within at least a part of the U-shape of second liner 160. As shown in FIG. 7, in certain embodiments, second dielectric material 170 may partially fill the U-shape of second liner 160 and may include upper surface 172 thereof below upper surface 134 of semiconductor layer 112. As shown in FIG. 8, in other embodiments, second dielectric material 170 may fill more of the U-shape of second liner 160 than shown in FIG. 7, and may include upper surface 172 coplanar, or closer to coplanar, with upper surface 134 of semiconductor layer 112.

First dielectric material 126 is different than second dielectric material 170. As described, in one example, first dielectric material 126 may include a first oxide (e.g., CVD oxide) and second dielectric material 170 may include a second oxide (e.g., an HDP-CVD oxide), the latter of which has a higher density than first dielectric material 126, regardless of the latter's form. Other dielectric materials may also be possible. In certain embodiments, first liner 122 may include at least one of silicon nitride and silicon oxynitride, and second liner 160 may include at least one of silicon oxy-carbonitride (SiOCN), silicon carbo-nitride (SiCN) and silicon boro-carbon nitride (SiBCN). Other liner materials are also possible. First liner 122 is thinner than second liner 160, which, in part, allows second liner 160 to protect semiconductor layer 112 from damage during the subsequent processing described herein. First liner 122 and second liner 160 are both U-shaped.

In other embodiments, isolation structure 100 includes lower portion 180 having first U-shaped liner 122 and first dielectric material 126 within first U-shaped liner 122. Isolation structure 100 also includes upper portion 182 over lower portion 180. Portions 180, 182 may be referred to as stacked together. Upper portion 182 has second U-shaped liner 160 and second dielectric material 170 within at least part of second U-shaped liner 160. As noted, first dielectric material 126 is different than second dielectric material 170. Further, first U-shaped liner 122 is thinner than second U-shaped liner 160. In certain embodiments, shown in FIG. 7, second dielectric material 170 partially fills second U-shaped liner 160 and includes upper surface 172 below upper surface 134 of semiconductor layer 112. As shown in FIG. 8, in other embodiments, second dielectric material 170 may fill more of the U-shape of second liner 160 than shown in FIG. 7, and may include upper surface 172 coplanar, or closer to coplanar, with upper surface 134 of semiconductor layer 112.

A lower section, e.g., bight portion 168, of second U-shaped liner 160 contacts an upper surface 184 of first dielectric material 126. The lower section, e.g., bight portion 168, of second U-shaped liner 160 also contacts end surfaces 186 of legs 140, 142 of first U-shaped liner 122. In this manner, first U-shaped liner 122 and bight portion 168 of second U-shaped liner 160 surround first dielectric material 126. As noted, second U-shaped liner 160 also abuts end surfaces 150, 152 of semiconductor layer 112 of substrate 110.

In the structures and method described above, a semiconductor material refers to a material whose conducting properties can be altered by doping with an impurity. Semiconductor materials include, for example, silicon-based semiconductor materials (e.g., silicon, silicon germanium, silicon germanium carbide, silicon carbide, etc.) and III-V compound semiconductors (i.e., compounds obtained by combining group III elements, such as aluminum (Al), gallium (Ga), or indium (In), with group V elements, such as nitrogen (N), phosphorous (P), arsenic (As) or antimony (Sb)) (e.g., GaN, InP, GaAs, or GaP). A pure semiconductor material and, more particularly, a semiconductor material that is not doped with an impurity for the purposes of increasing conductivity (i.e., an undoped semiconductor material) is referred to in the art as an intrinsic semiconductor. A semiconductor material that is doped with an impurity for the purposes of increasing conductivity (i.e., a doped semiconductor material) is referred to in the art as an extrinsic semiconductor and will be more conductive than an intrinsic semiconductor made of the same base material. That is, extrinsic silicon will be more conductive than intrinsic silicon; extrinsic silicon germanium will be more conductive than intrinsic silicon germanium; and so on. Furthermore, it should be understood that different impurities (i.e., different dopants) can be used to achieve different conductivity types (e.g., P-type conductivity and N-type conductivity) and that the dopants may vary depending upon the different semiconductor materials used. For example, a silicon-based semiconductor material (e.g., silicon, silicon germanium, etc.) is typically doped with a Group III dopant, such as boron (B) or indium (In), to achieve P-type conductivity, whereas a silicon-based semiconductor material is typically doped a Group V dopant, such as arsenic (As), phosphorous (P) or antimony (Sb), to achieve N-type conductivity. A gallium nitride (GaN)-based semiconductor material is typically doped with magnesium (Mg) to achieve P-type conductivity and with silicon (Si) or oxygen to achieve N-type conductivity. Those skilled in the art will also recognize that different conductivity levels will depend upon the relative concentration levels of the dopant(s) in a given semiconductor region. Furthermore, when a semiconductor region or layer is described as being at a higher conductivity level than another semiconductor region or layer, it is more conductive (less resistive) than the other semiconductor region or layer; whereas, when a semiconductor region or layer is described as being at a lower conductivity level than another semiconductor region or layer, it is less conductive (more resistive) than that other semiconductor region or layer.

Embodiments of the disclosure provide various technical and commercial advantages, examples of which are discussed herein. For example, the second liner prevents exposure of end surfaces of a semiconductor layer of the substrate during subsequent processing, which prevents damage such as thinning, agglomeration and/or oxidation that can negatively affect performance of a transistor formed using the semiconductor layer. The second liner also reduces an overall step height of the isolation structure.

The structure and method as described above are used in the fabrication of integrated circuit chips. The resulting integrated circuit chips can be distributed by the fabricator in raw wafer form (that is, as a single wafer that has multiple unpackaged chips), as a bare die, or in a packaged form. In the latter case the chip is mounted in a single chip package (such as a plastic carrier, with leads that are affixed to a motherboard or other higher-level carrier) or in a multichip package (such as a ceramic carrier that has either or both surface interconnections or buried interconnections). In any case the chip is then integrated with other chips, discrete circuit elements, and/or other signal processing devices as part of either (a) an intermediate product, such as a motherboard, or (b) an end product. The end product can be any product that includes integrated circuit chips, ranging from toys and other low-end applications to advanced computer products having a display, a keyboard or other input device, and a central processor.

The terminology used herein is for the purpose of describing particular embodiments only and is not intended to be limiting to the disclosure. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof. “Optional” or “optionally” means that the subsequently described event or circumstance may or may not occur, and that the description includes instances where the event occurs and instances where it does not.

Approximating language, as used herein throughout the specification and claims, may be applied to modify any quantitative representation that could permissibly vary without resulting in a change in the basic function to which it is related. Accordingly, a value modified by a term or terms, such as “about”, “approximately” and “substantially”, are not to be limited to the precise value specified. In at least some instances, the approximating language may correspond to the precision of an instrument for measuring the value. Here and throughout the specification and claims, range limitations may be combined and/or interchanged, such ranges are identified and include all the sub-ranges contained therein unless context or language indicates otherwise. “Approximately” as applied to a particular value of a range applies to both values, and unless otherwise dependent on the precision of the instrument measuring the value, may indicate +/−10% of the stated value(s).

The corresponding structures, materials, acts, and equivalents of all means or step plus function elements in the claims below are intended to include any structure, material, or act for performing the function in combination with other claimed elements as specifically claimed. The description of the present disclosure has been presented for purposes of illustration and description but is not intended to be exhaustive or limited to the disclosure in the form disclosed. Many modifications and variations will be apparent to those of ordinary skill in the art without departing from the scope and spirit of the disclosure. The embodiment was chosen and described in order to best explain the principles of the disclosure and the practical application, and to enable others of ordinary skill in the art to understand the disclosure for various embodiments with various modifications as are suited to the particular use contemplated.

What is claimed is:

1. An isolation structure for a substrate, the isolation structure comprising:
a lower portion having a first liner;
an upper portion having a second liner vertically over the first liner; and
a first dielectric material surrounded by the second liner from above and by the first liner from below and laterally.

2. The isolation structure of claim 1, wherein the substrate includes a semiconductor layer having end surfaces, and the second liner abuts the end surfaces of the semiconductor layer of the substrate.

3. The isolation structure of claim 2, wherein the second liner is U-shaped, and further comprising a second dielectric material within at least a part of the U-shape of the second liner.

4. The isolation structure of claim 3, wherein the second dielectric material partially fills the U-shape of the second liner and includes an upper surface below an upper surface of the semiconductor layer.

5. The isolation structure of claim 3, wherein the first dielectric material is different than the second dielectric material.

6. The isolation structure of claim 1, wherein the first liner includes at least one of silicon nitride and silicon oxynitride, and the second liner includes at least one of silicon oxy-carbonitride, silicon carbo-nitride and silicon boro-carbon nitride.

7. The isolation structure of claim 1, wherein the first liner is U-shaped and the second liner is U-shaped.

8. The isolation structure of claim 1, wherein the first liner is thinner than the second liner.

9. An isolation structure for a substrate, the isolation structure comprising:
a lower portion having a first U-shaped liner and a first dielectric material within the first U-shaped liner; and
an upper portion over the lower portion, the upper portion having a second U-shaped liner and a second dielectric material within at least part of the second U-shaped liner,
wherein a lower section of the second U-shaped liner contacts an upper surface of the first dielectric material.

10. The isolation structure of claim 9, wherein the substrate includes a semiconductor layer having end surfaces, and the second U-shaped liner abuts the end surfaces of the semiconductor layer.

11. The isolation structure of claim 10, wherein the second dielectric material partially fills the second U-shaped liner and includes an upper surface below an upper surface of the semiconductor layer.

12. The isolation structure of claim 9, wherein the first dielectric material is different than the second dielectric material.

13. The isolation structure of claim 12, wherein the first dielectric material includes a first oxide, and the second dielectric material includes a second, higher density oxide.

14. The isolation structure of claim 9, wherein the first U-shaped liner includes at least one of silicon nitride and silicon oxynitride, and the second U-shaped liner includes at least one of silicon oxy-carbonitride, silicon carbo-nitride and silicon boro-carbon nitride.

15. The isolation structure of claim 9, wherein the first U-shaped liner is thinner than the second U-shaped liner.

16. A method, comprising:
forming a first U-shaped liner within a trench extending through a semiconductor layer of a substrate;
filling at least a portion of the trench with a first dielectric material;
forming a second U-shaped liner in the trench over the first dielectric material in the trench and below an upper surface of the semiconductor layer; and
filling at least part of the second U-shaped liner with a second dielectric material.

17. The method of claim 16, wherein the semiconductor layer has end surfaces, and the second U-shaped liner abuts the end surfaces of the semiconductor layer.

18. The method of claim 16, wherein the second dielectric material partially fills the second U-shaped liner and includes an upper surface below an upper surface of the semiconductor layer.

19. The method of claim 16, wherein the first U-shaped liner includes at least one of silicon nitride and silicon oxynitride, and the second U-shaped liner includes at least one of silicon oxy-carbonitride, silicon carbo-nitride and silicon boro-carbon nitride.

20. The method of claim 16, wherein the first U-shaped liner is thinner than the second U-shaped liner.
